(19) United States
(12) Patent Application Publication
(10) Pub. No.: US 2025/0218510 A1
(43) Pub. Date: Jul. 3, 2025

(54) SEMICONDUCTOR DEVICE AND OPERATING METHOD OF SEMICONDUCTOR DEVICE

(71) Applicant: SK hynix Inc., Icheon (KR)

(72) Inventors: Gap Sok DO, Icheon-si (KR); Yoon Cheol BAE, Icheon-si (KR)

(21) Appl. No.: 18/651,539

(22) Filed: Apr. 30, 2024

(30) Foreign Application Priority Data
Dec. 27, 2023 (KR) 10-2023-0192165

(51) Int. Cl. G11C 13/00

(52) U.S. Cl. CPC G11C 13/0069; G11C 13/0026; G11C 13/0028

(57) ABSTRACT

A semiconductor device may include a memory cell array including a plurality of memory cells arranged at locations where a plurality of word lines intersect with a plurality of bit lines, a row decoder configured to drive the plurality of word lines and a column decoder configured to drive the plurality of bit lines, wherein each of the plurality of memory cells has a set state or a reset state according to a normal write operation performed thereon, the plurality of memory cells include first memory cells in a specific area of the memory cell array, and the row decoder and the column decoder control a bit line and a word line coupled to a corresponding one of the first memory cells to increase a margin between the set state and the reset state of the corresponding first memory cell.

### CROSS-REFERENCE TO RELATED APPLICATION

This application claims priority under 35 U.S.C. § 119(a) to Korean Patent Application No. 10-2023-0192165 filed on Dec. 27, 2023, which is incorporated herein by reference in its entirety.

### BACKGROUND

### 1. Technical Field

Embodiments of the present disclosure relate to an integrated circuit technology, and more particularly, to a semiconductor device and an operating method of the semiconductor device.

### 2. Related Art

Recently, with the miniaturization, low power consumption, high performance, diversification, and the like of electronic devices, there is a demand for semiconductor devices capable of storing information in various electronic devices such as computers and portable communication devices. The semiconductor devices may be broadly classified into volatile memory devices and nonvolatile memory devices. The volatile memory device may retain data only when power is supplied, and the nonvolatile memory device may retain data even when no power is supplied.

The representative nonvolatile memory device is a NAND type memory, and next-generation memories currently under development include a ferroelectric RAM (FRAM), a magnetic RAM (MRAM), a phase-change RAM (PRAM), a polymer RAM (PORAM), a resistance RAM (ReRAM), and the like.

### SUMMARY

In an embodiment, a semiconductor device may include: a memory cell array including a plurality of memory cells arranged at locations where a plurality of word lines intersect with a plurality of bit lines, a row decoder configured to drive the plurality of word lines and a column decoder configured to drive the plurality of bit lines, wherein each of the plurality of memory cells has a set state or a reset state according to a normal write operation performed thereon, the plurality of memory cells include first memory cells in a specific area of the memory cell array, and the row decoder and the column decoder control a bit line and a word line coupled to a corresponding one of the first memory cells to increase a margin between the set state and the reset state of the corresponding first memory cell.

In an embodiment, a semiconductor device may include: a control circuit configured to generate a current direction control signal, a row address signal, and a column address signal on the basis of a command signal, an address signal, and a data signal, a current direction control circuit configured to provide a positive bias voltage to one of a row voltage line and a column voltage line on the basis of the current direction control signal, and to provide a negative bias voltage to the other voltage line, the positive bias voltage being one of a first positive bias voltage, a second positive bias voltage, and a third positive bias voltage, the negative bias voltage being one of a first negative bias voltage, a second negative bias voltage, and a third negative bias voltage corresponding to the positive bias voltage, a memory cell array including a plurality of memory cells arranged at locations where a plurality of word lines intersect with a plurality of bit lines, a row decoder configured to select at least one word line from the plurality of word lines on the basis of the row address signal, and to drive the selected word line to a voltage level of the row voltage line, and a column decoder configured to select at least one bit line from the plurality of bit lines on the basis of the column address signal, and to drive the selected bit line to a voltage level of the column voltage line.

In an embodiment, an operating method of a semiconductor device may include: performing a normal write operation to make a memory cell have a set state or a reset state, determining required reliability of data stored in the memory cell, increasing, in response to the determination, a threshold voltage level of the memory cell and decreasing the increased threshold voltage level of the memory cell according to whether the memory cell has the set state or the reset state.

### BRIEF DESCRIPTION OF THE DRAWINGS

FIG. 1 is a diagram illustrating a configuration of a semiconductor device in accordance with an embodiment of the present disclosure.

FIGS. 2, 3, 4, 5, 6, 7, 8, 9A, and 9B are diagrams for describing an operation of the semiconductor device in accordance with an embodiment of the present disclosure.

FIG. 10 is a flowchart for describing an operating method of the semiconductor device in accordance with an embodiment of the present disclosure.

### DETAILED DESCRIPTION

Various embodiments are directed to a semiconductor device capable of performing a write operation that can improve data reliability and an operating method of the semiconductor device.

By securing a wide margin between a set state and a reset state, it is possible to improve the reliability of data storage in a semiconductor device.

Hereafter, embodiments in accordance with the technical spirit of the present disclosure will be described with reference to the accompanying drawings.

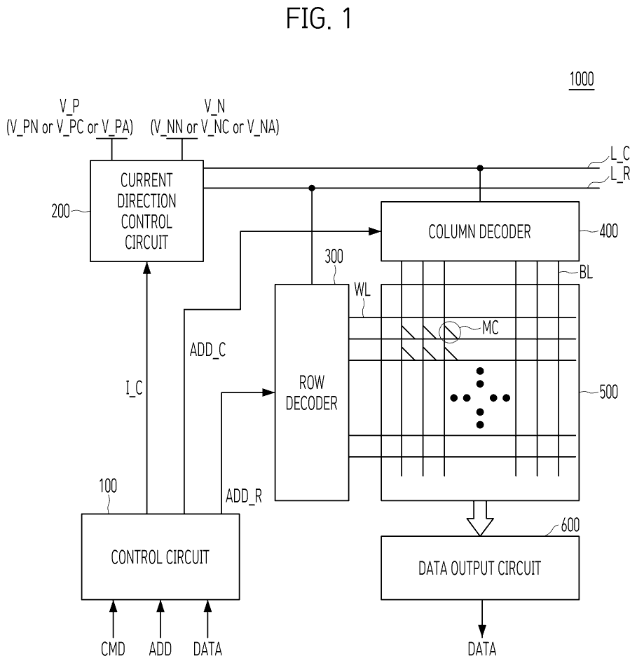

FIG. 1 is a diagram illustrating configuration of a semiconductor device 1000 in accordance with an embodiment of the present disclosure.

Referring to FIG. 1, the semiconductor device 1000 in accordance with an embodiment of the present disclosure may include a controller (e.g., a control circuit) 100, a current direction control circuit 200, a row decoder 300, a column decoder 400, a memory cell array 500, and a data output circuit 600.

The control circuit 100 may control the current direction control circuit 200, the row decoder 300, and the column decoder 400 on the basis of a command signal CMD, an address signal ADD, and a data signal DATA, thereby storing data in the memory cell array 500 or outputting the data stored in the memory cell array 500 to the outside of the semiconductor device 1000 through the data output circuit 600. In such a case, an operation for storing data in the memory cell array 500 is referred to as a write operation, and an operation for outputting the data stored in the memory cell array 500 to the outside of the semiconductor device 1000 is referred to as a read operation.

For example, the control circuit 100 that performs a write operation or a read operation may generate a current direction control signal I_C, a row address signal ADD_R, and a column address signal ADD_C on the basis of the command signal CMD, the address signal ADD, and the data signal DATA.

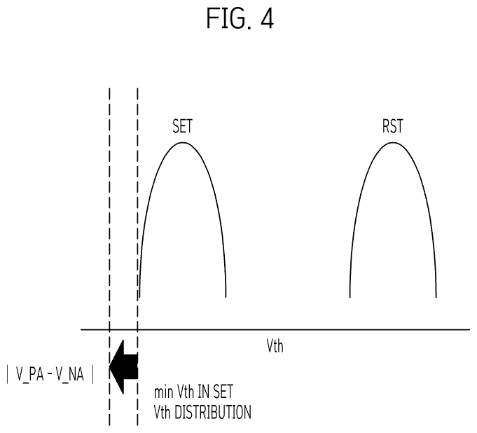

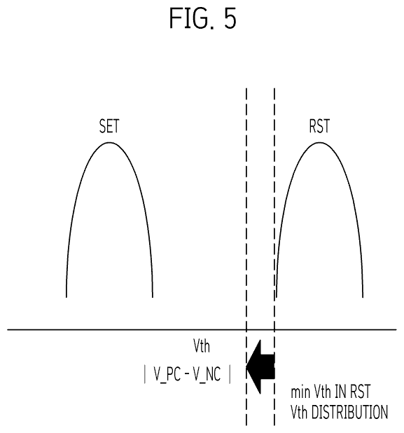

More specifically, for example, the control circuit 100 may generate the current direction control signal I_C on the basis of the command signal CMD, the data signal DATA, and the address signal ADD, and provide the current direction control signal I_C to the current direction control circuit 200. In such a case, the control circuit 100 may determine whether the command signal CMD is a write command or a read command. The control circuit 100 may also classify the address signal ADD into the row address signal ADD_R and the column address signal ADD_C. The control circuit 100 may determine a location of each of a plurality of memory cells on which a normal write operation is performed according to an address signal ADD_C indicating an address of the memory cell. When the command signal CMD is a write command, the control circuit 100 may determine whether the data signal DATA indicate set data or reset data, and determine whether data to be stored in a memory cell through a write operation on the basis of the address signal ADD is to be stored in a normal storage area or a storage area (or a specific area) with a higher reliability than the normal storage area. The control circuit 100 may, after a normal write operation is performed on a plurality of memory cells of the memory cell array 500 including first memory cells in a specific area of the memory cell array 500, drive a bit line and a word line coupled to a corresponding one of the first memory cells in the specific area. For example, after the control circuit 100 has applied a first voltage difference to each of the plurality of memory cells including the first memory cells during the normal write operation, the control circuit 100 may drive the bit line and the word line for a set time interval to apply a third voltage difference (e.g., |V_PA-V_NA| in FIG. 4) to the corresponding one of the first memory cells. The third voltage difference applied for the set time interval may be smaller than the first voltage difference applied during the normal write operation. After the set time interval, the control circuit 100 may further drive the bit line and the word line to apply a second voltage difference (e.g., |V_PC-V_NC| in FIG. 5) to the first memory cell. For example, the control circuit 100 may drive the bit line to a voltage level higher than that of the word line, and the second voltage difference may be greater than the third voltage difference and smaller than the first voltage difference. As a result, a margin between a set state and a reset state of the first memory cell may be increased to ensure relatively high reliability of data to be stored in the first memory cell of the specific area.

When the command signal CMD is a write command, the control circuit 100 in accordance with an embodiment of the present disclosure may generate the type of data to be stored in a memory cell on the basis of the data signal DATA, and generate the current direction control signal I_C according to a location of an area for storing data on the basis of the address signal ADD.

The control circuit 100 may generate the row address signal ADD_R on the basis of the command signal CMD and the address signal ADD, and provide the row address signal ADD_R to the row decoder 300.

The control circuit 100 may generate the column address signal ADD_C on the basis of the command signal CMD and the address signal ADD, and provide the column address signal ADD_C to the column decoder 400.

The current direction control circuit 200 may provide a positive bias voltage V_P and a negative bias voltage V_N to a row voltage line L_R and a column voltage line L_C, respectively, and vice versa, on the basis of the current direction control signal I_C.

For example, when the current direction control circuit 200 provides the positive bias voltage V_P to the row voltage line L_R on the basis of the current direction control signal I_C, the current direction control circuit 200 may provide the negative bias voltage V_N to the column voltage line L_C. When the current direction control circuit 200 provides the positive bias voltage V_P to the column voltage line L_C on the basis of the current direction control signal I_C, the current direction control circuit 200 may provide the negative bias voltage V_N to the row voltage line L_R. In such a case, the positive bias voltage V_P may include a first positive bias voltage V_PN, a second positive bias voltage V_PC, and a third positive bias voltage V_PA having mutually different voltage levels. The negative bias voltage V_N may include a first negative bias voltage V_NN, a second negative bias voltage V_NC, and a third negative bias voltage V_NA having mutually different voltage levels. In a case where the positive bias voltage V_P includes the first, second, and third positive bias voltages V_PN, V_PC, and V_PA and the negative bias voltage V_N includes the first, second, and third negative bias voltages V_NN, V_NC, and V_NA, when the current direction control circuit 200 provides one of the first, second, and third positive bias voltages V_PN, V_PC, and V_PA to the row voltage line L_R on the basis of the current direction control signal I_C, the current direction control circuit 200 may provide a corresponding one of the first, second, and third negative bias voltages V_NN, V_NC, and V_NA to the column voltage line L_C. When the current direction control circuit 200 provides one of the first, second, and third positive bias voltages V_PN, V_PC, and V_PA to the column voltage line L_C on the basis of the current direction control signal I_C, the current direction control circuit 200 may provide a corresponding one of the first, second, and third negative bias voltages V_NN, V_NC, and V_NA to the row voltage line L_R. For example, the first positive bias voltage V_PN may correspond to the first negative bias voltage V_NN. The second positive bias voltage V_PC may correspond to the second negative bias voltage V_NC. The third positive bias voltage V_PA may correspond to the third negative bias voltage V_NA.

The row decoder 300 may select at least one first line (e.g., word lines) WL on the basis of the row address signal ADD_R, and drive the selected word line WL to a voltage level of the row voltage line L_R.

The column decoder 400 may select at least one second line (e.g., bit lines) BL on the basis of the column address signal ADD_C, and drive the selected bit line BL to a voltage level of the column voltage line L_C.

The memory cell array 500 may include a plurality of memory cells MC and may be an area where a plurality of word lines WL intersect with a plurality of bit lines BL. In such a case, each memory cell MC may be located at a location where one word line WL intersects with one bit line BL, and each memory cell MC may be electrically connected between the word line WL and the bit line BL. The memory cell MC may store data in a first state (e.g., a set state) or a second state (e.g., a reset state) depending on the polarity of a voltage provided from each of the word lines WL and each of the bit lines BL. That is, the memory cell MC may store set data or reset data depending on the direction of a current flowing through the memory cell MC. The memory cell MC may be a self-selecting memory including a chalcogenide alloy.

The data output circuit 600 may sense data stored in the memory cell MC through the word line WL or the bit line BL, and output the sensed data.

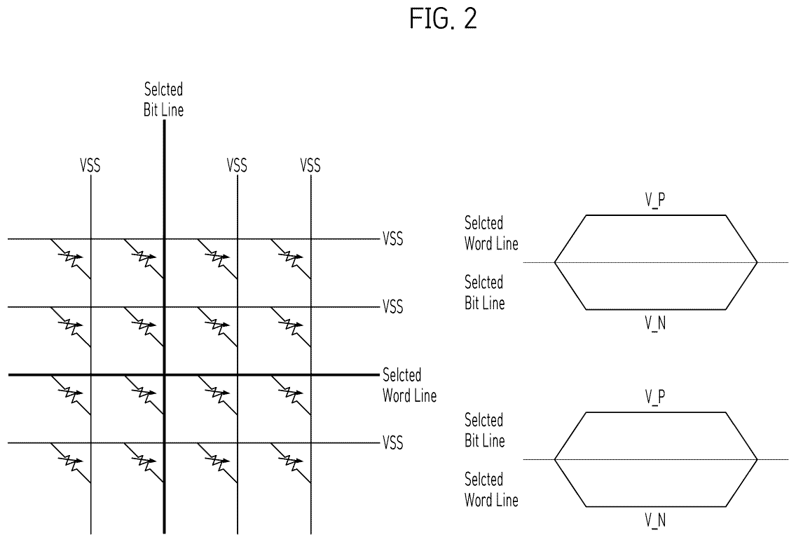

FIGS. 2 to 9 are diagrams for explaining the operation of the semiconductor device in accordance with an embodiment of the present disclosure.

Memory cells MC may be electrically connected between the plurality of word lines WL and the plurality of bit lines BL. For example, each memory cell MC may be electrically connected between a corresponding one of the plurality of word lines WL and a corresponding one of the plurality of bit lines BL. The direction of a current flowing through the memory cell MC may be determined depending on the polarity of a voltage applied to each of a selected word line Selected Word Line and a selected bit line Selected Bit Line, and the memory cell MC may be converted to a set state or a reset state depending on the direction of the current. In such a case, an operation for converting the memory cell MC to a set state or a reset state may be referred to as a write operation. An operation for converting the memory cell MC to the set state is referred to as a set write operation, and an operation for converting the memory cell MC to the reset state is referred to as a reset write operation.

FIG. 2 is a diagram for explaining illustrating a positive bias voltage and a negative bias voltage of the semiconductor device in accordance with an embodiment of the present disclosure.

As described above, the positive bias voltage V_P may include the first, second, and third positive bias voltages V_PN, V_PC, and V_PA, and the negative bias voltage V_N may include the first, second, and third negative bias voltages V_NN, V_NC, and V_NA.

Referring to FIG. 2, the first positive bias voltage V_PN may be a voltage with the highest voltage level among the first, second, and third positive bias voltages V_PN, V_PC, and V_PA. The third positive bias voltage V_PA may be a voltage with the lowest voltage level among the first, second, and third positive bias voltages V_PN, V_PC, and V_PA. The second positive bias voltage V_PC may be a voltage with a voltage level between the voltage level of the first positive bias voltage V_PN and the voltage level of the third positive bias voltage V_PA.

The first negative bias voltage V_NN may be a voltage with the lowest voltage level among the first, second, and third negative bias voltages V_NN, V_NC, and V_NA. The third negative bias voltage V_NA may be a voltage with the highest voltage level among the first, second, and third negative bias voltages V_NN, V_NC, and V_NA. The second negative bias voltage V_NC may be a voltage with a voltage level between the voltage level of the first negative bias voltage V_NN and the voltage level of the third negative bias voltage V_NA.

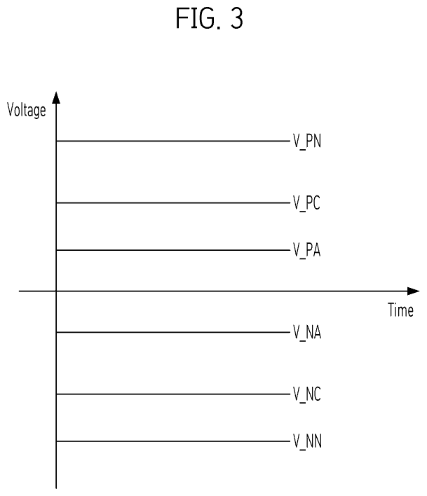

FIG. 3 is a diagram for explaining an operation in which voltages with mutually different polarities are provided to the memory cells of the semiconductor device in accordance with an embodiment of the present disclosure.

Referring to FIGS. 1, 2, and 3, one of the plurality of word lines WL may be selected by the row decoder 300, and one of the plurality of bit lines BL may be selected by the column decoder 400.

The selected word line Selected Word Line may be driven to the voltage level of the row voltage line L_R. In such a case, the row voltage line L_R may be a line connected to the row decoder 300 and providing a driving voltage of the row decoder 300. The row decoder 300 may select one of the plurality of word lines WL on the basis of the row address signal ADD_R and drive the selected word line WL with a voltage provided from the row voltage line L_R.

The selected bit line Selected Bit Line may be driven to the voltage level of the column voltage line L_C. In such a case, the column voltage line L_C may be a line connected to the column decoder 400 and providing a driving voltage of the column decoder 400. The column decoder 400 may select one of the plurality of bit lines BL on the basis of the column address signal ADD_C, and drive the selected bit line BL with a voltage provided from the column voltage line L_C.

When the positive bias voltage V_P is provided to the row voltage line L_R and the negative bias voltage V_N is provided to the column voltage line L_C, the selected word line Selected Word Line may be driven to the level of the positive bias voltage V_P and the selected bit line Selected Bit Line may be driven to the level of the negative bias voltage V_N.

When the positive bias voltage V_P is provided to the column voltage line L_C and the negative bias voltage V_N is provided to the row voltage line L_R, the selected bit line Selected Bit Line may be driven to the level of the positive bias voltage V_P and the selected word line Selected Word Line may be driven to the level of the negative bias voltage V_N.

In such a case, the positive bias voltage V_P may include the first, second, and third positive bias voltages V_PN, V_PC, and V_PA with mutually different levels. Accordingly, one of the first, second, and third positive bias voltages V_PN, V_PC, and V_PA may be provided to one of the column voltage line L_C and the row voltage line L_R. Therefore, one of the selected bit lines Selected Bit Line and the selected word lines Selected Word Line may be driven to the bias voltage level of one of the first, second, and third positive bias voltages V_PN, V_PC, and V_PA.

The negative bias voltage V_N may include the first, second, and third negative bias voltages V_NN, V_NC, and V_NA with mutually different levels. Accordingly, one of the first, second, and third negative bias voltages V_NN, V_NC, and V_NA may be provided to one of the column voltage line L_C and the row voltage line L_R. Therefore, one of the selected bit lines Selected Bit Line and the selected word lines Selected Word Line may be driven to the bias voltage level of one of the first, second, and third negative bias voltages V_NN, V_NC, and V_NA.

More specifically, for example, when one of the selected bit line Selected Bit Line and the selected word line Selected Word Line is driven to the first positive bias voltage V_PN, the other line may be driven to the first negative bias voltage V_NN. When one of the selected bit line Selected Bit Line and the selected word line Selected Word Line is driven to the second positive bias voltage V_PC, the other line may be driven to the second negative bias voltage V_NC. When one of the selected bit line Selected Bit Line and the selected word line Selected Word Line is driven to the third positive bias voltage V_PA, the other line may be driven to the third negative bias voltage V_NA.

FIGS. 4 and 5 are diagrams for explaining the level of a bias voltage provided to a memory cell of the semiconductor device in accordance with an embodiment of the present disclosure and the threshold voltage distribution of memory cells of the semiconductor device.

Depending on the levels of the first positive bias voltage V_PN and the first negative bias voltage V_NN, the memory cell MC may transition to a set state SET or a reset state RST. For example, when the selected bit line Selected Bit Line is driven to the level of the first positive bias voltage V_PN and the selected word line Selected Word Line is driven to the level of the first negative bias voltage V_NN, the memory cell MC may transition to the set state. In such a case, an operation in which the memory cell MC transitions to the set state may be referred to as a set write operation. When the selected word line Selected Word Line is driven to the level of the first positive bias voltage V_PN and the selected bit line Selected Bit Line is driven to the level of the first negative bias voltage V_NN, the memory cell MC may transition to a reset state. In such a case, an operation in which the memory cell MC transitions to the reset state may be referred to as a reset write operation.

FIG. 4 illustrates a distribution SET of threshold voltages Vth of memory cells MC subjected to the set write operation, and a distribution RESET of threshold voltages Vth of memory cells MC subjected to the reset write operation, in accordance with an embodiment of the present disclosure.

Referring to FIG. 4, a level difference IV_PA-V_NAI between the third positive bias voltage V_PA and the third negative bias voltage V_NA may be smaller than the level of a minimum threshold voltage min Vth in the threshold voltage distribution SET of the memory cells MC in the set state. In an embodiment, the level difference IV_PA-V_NAI between the third positive bias voltage V_PA and the third negative bias voltage V_NA may be sufficiently small to avoid turning on the memory cells MC in the set state. For example, the level difference IV_PA-V_NAI between the third positive bias voltage V_PA and the third negative bias voltage V_NA may be in a range from about 50% to 98% of the minimum threshold voltage min Vth in the threshold voltage distribution SET of the memory cells MC in the set state. When the level difference IV_PA-V_NAI between the third positive bias voltage V_PA and the third negative bias voltage V_NA is smaller than about 50% of the minimum threshold voltage min Vth, the threshold voltage distribution RESET for the memory cells MC may not be sufficiently shifted to desirably high threshold voltage levels. When the level difference IV_PA-V_NAI between the third positive bias voltage V_PA and the third negative bias voltage V_NA is greater than about 98% of the minimum threshold voltage min Vth, avoiding turning on the memory cells MC in the set state may not be ensured.

Referring to FIG. 5, a level difference IV_PC-V_NCI between the second positive bias voltage V_PC and the second negative bias voltage V_NC may be smaller than the level of a minimum threshold voltage min Vth in the threshold voltage distribution RST of the memory cell MC in the reset state. In an embodiment, the level difference IV_PC-V_NCI between the second positive bias voltage V_PC and the second negative bias voltage V_NC may be sufficient to avoid turning on memory cells MC in the reset state while turning on memory cells MC in the set state. For example, the level difference IV_PC-V_NCI between the second positive bias voltage V_PC and the second negative bias voltage V_NC may be may be greater than about 80% to about 100% of the level of a minimum threshold voltage min Vth in the threshold voltage distribution RST of the memory cells MC in the reset state, based on the threshold voltage distribution RST after the normal write operation has been completed on the memory cells MC and before the threshold voltage distributions SET and RESET are increased as described above.

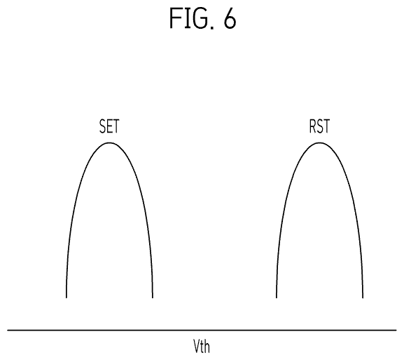

FIGS. 6 to 9 are diagrams for explaining a write operation of the semiconductor device and threshold voltage distributions of the memory cells, in accordance with an embodiment of the present disclosure.

FIG. 6 may be a diagram illustrating threshold voltage distributions of memory cells according to a normal write operation. In such a case, the normal write operation may include a write operation in which the first positive bias voltage V_PN and the first negative bias voltage V_NN are provided to the memory cell.

When the selected bit line Selected Bit Line is driven to the level of the first positive bias voltage V_PN and the selected word line Selected Word Line is driven to the level of the first negative bias voltage V_NN, the threshold voltage of the memory cell MC may be included in the threshold voltage distribution SET of the set state illustrated in FIG. 6.

When the selected word line Selected Word Line is driven to the level of the first positive bias voltage V_PN and the selected bit line Selected Bit Line is driven to the level of the first negative bias voltage V_NN, the threshold voltage of the memory cell MC may be included in the threshold voltage distribution RST of the reset state illustrated in FIG. 6.

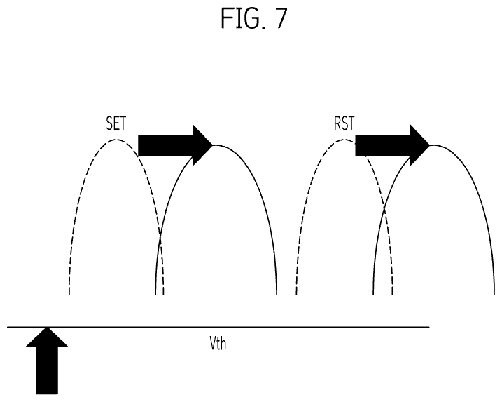

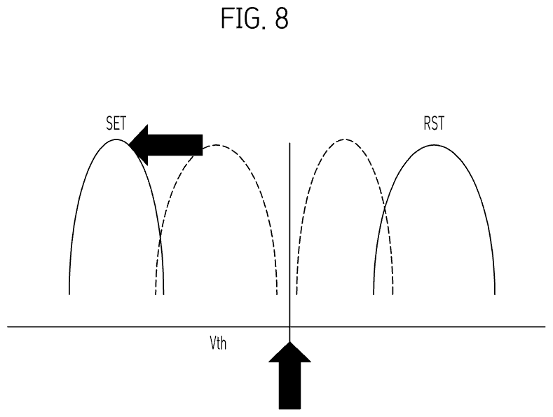

FIGS. 7 and 8 are diagrams for explaining an operation for widening a margin between the set state and the reset state of the memory cell after the normal write operation of the semiconductor device in accordance with an embodiment of the present disclosure. For example, a row decoder (e.g., the row decoder 300 in FIG. 1) and a column decoder (e.g., the column decoder 400 in FIG. 1) according to an embodiment of the present disclosure may control a bit line and a control line coupled to a corresponding one of memory cells to increase a margin between the set state and the reset state of the memory cell. The row decoder and the column decoder may repeat controlling of a bit line and a word line to increase a margin between threshold voltage distributions of a plurality of memory cells in a specific area of a memory array (e.g., the memory cell array 500 in FIG. 1). Specifically, FIGS. 7 and 8 illustrate increasing a margin between a threshold voltage distribution (or a set threshold voltage distribution) SET of memory cells in the set state and a threshold voltage distribution (or a reset threshold voltage distribution) RST of memory cells in the reset state in accordance with an embodiment of the present disclosure. For example, a margin between the set threshold voltage distribution SET and the reset threshold voltage distribution RST may be a difference between a minimum threshold voltage of the reset threshold voltage distribution RST and a maximum threshold voltage of the set threshold voltage distribution SET.

Referring to FIG. 7, the third positive bias voltage V_PA and the third negative bias voltage V_NA may be provided to the memory cell MC subjected to the normal write operation. In such a case, the threshold voltage distribution SET of memory cells MC in the set state and the threshold voltage distribution RST of memory cells MC in the reset state may be shifted toward higher threshold voltage levels. That is, when the third positive bias voltage V_PA and the third negative bias voltage V_NA are provided to the memory cell MC, the threshold voltage level of the memory cell MC in the set state or the reset state may be increased. The amount of increase in the threshold voltage level of the memory cell MC may be determined according to a time interval during which the third positive bias voltage V_PA and the third negative bias voltage V_NA are provided to the memory cell MC.

The semiconductor device in accordance with an embodiment of the present disclosure may provide the third positive bias voltage V_PA and the third negative bias voltage V_PA to the memory cell MC for a set time interval as an operation for increasing threshold voltages of the memory cells MC to widen a margin between the set state and the reset state after the normal write operation is performed. In such a case, one of the selected bit line Selected Bit Line and the selected word line Selected Word Line may be driven to the third positive bias voltage V_PA for a set time interval, and the other line may be driven to the third negative bias voltage V_NA for the set time interval. In an embodiment, the time interval may be set to make a sufficient margin between the set threshold voltage distribution SET and the reset threshold voltage distribution RST to ensure the reliability of data to be stored in the memory cell MC coupled to the selected bit line and the selected word line. For example, the time interval may be set to be equal to or greater than 1 μs. In the above-described embodiments, the semiconductor device may provide the third positive bias voltage V_PA and the third negative bias voltage V_NA to a selected memory cell to increase the threshold voltage of the selected memory cell. However, embodiments of the present disclosure are not limited thereto. For example, the semiconductor device may provide the third positive bias voltage V_PA to only one of a selected bit line Selected Bit Line and a selected word line Selected Word Line, or provide the third negative bias voltage V_NA to only one of a selected bit line Selected Bit Line and a selected word line Selected Word Line. As a result, threshold voltages of a plurality of memory cells connected to the selected bit line Selected Bit Line or threshold voltages a plurality of memory cells connected to the selected word line Selected Word Line may be increased at a time, thereby increasing a speed of increasing the threshold voltages of the memory cells MC in the set state and the reset state.

Referring to FIG. 8, after the third positive bias voltage V_PA and the third negative bias voltage V_NA are provided to the memory cell MC for the set time interval, the second positive bias voltage V_PC and the second negative bias voltage V_NC may be provided to the memory cell MC. In such a case, the second positive bias voltage V_PC may be provided to the column voltage line L_C and the second negative voltage V_NC may be provided to the row voltage line L_R, so that the selected bit line Selected Bit Line may be driven to the second positive bias voltage V_PC and the selected word line Selected Word Line may be driven to the second negative bias voltage V_NC. That is, the selected bit line Selected Bit Line and the selected word line Selected Word Line may be driven to the second positive bias voltage V_PC and the second negative bias voltage V_NC, respectively, so that a current flows through the memory cell MC in the same direction as during the set write operation.

In a state in which the threshold voltage levels of the memory cell MC in the set state and the reset state have been increased, when the selected bit line Selected Bit Line is driven to the second positive bias voltage V_PC and the selected word line Selected Word Line is driven to the second negative bias voltage V_NC, only the threshold voltage levels of memory cells MC in the set state may be decreased, whereas those of memory cells MC in the reset state may remain substantially the same. The difference between the voltage levels provided to the memory cell MC is higher than the threshold voltage level of the memory cells MC in the set state, and thus only a memory cell in the set state is turned on. As a result, only the threshold voltage level of the turned-on memory cell MC in the set state SET may be decreased. In other words, the set threshold voltage distribution SET may be decreased, whereas the reset threshold voltage distribution RST may remain substantially the same.

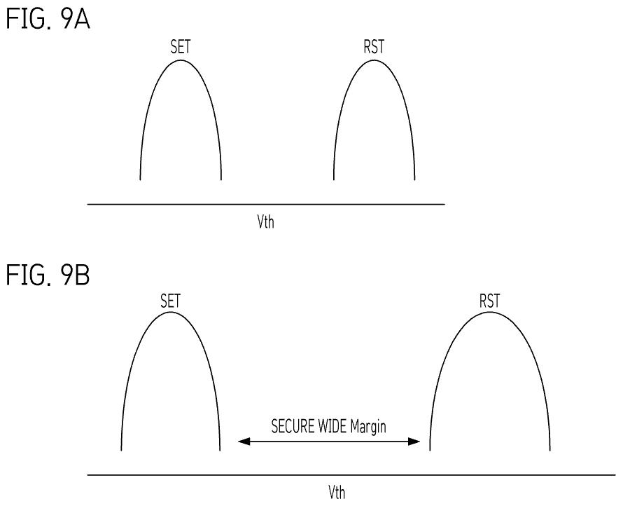

FIG. 9A illustrates the threshold voltage distribution SET of the memory cell MC in the set state and the threshold voltage distribution RST of the memory cell MC in the reset state during the normal write operation. Specifically, FIG. 9A illustrates the set threshold voltage distribution SET and the reset threshold voltage distribution RST, after a normal write operation has been completed on the memory cells MC.

FIG. 9B illustrates, the set threshold voltage distribution SET and the reset threshold voltage distribution RST with an increased margin therebetween, by performing an operation of increasing the threshold voltage levels of memory cells MC in both of the set state and the reset state and an operation of decreasing only the threshold voltage levels of memory cell MC in the set state, as described above with reference to FIGS. 7 and 8.

Comparing FIG. 9A with FIG. 9B, it can be seen that a margin Margin between the threshold voltage distribution SET of the memory cells MC in the set state and the threshold voltage distribution RST of the memory cells MC in the reset state is wider in FIG. 9B than that in FIG. 9A.

The semiconductor device in accordance with an embodiment of the present disclosure may cause a memory cell to transition to a set state or a reset state through a normal write operation. When data requiring high reliability is stored in a memory cell, the semiconductor device in accordance with an embodiment of the present disclosure may perform a normal write operation on the memory cell and then additionally perform an operation for widening a margin between the set state and the reset state.

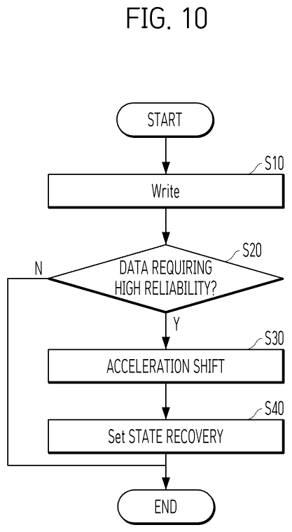

FIG. 10 is a flowchart for explaining an operating method of the semiconductor device in accordance with an embodiment of the present disclosure.

Referring to FIG. 10, the semiconductor device in accordance with an embodiment of the present disclosure may include a normal write operation S10, an operation S20 of determining the required reliability of data, an acceleration shift operation S30, and a set state initialization operation S40.

The normal write operation S10 may be an operation performed when the command signal CMD is a write command. In an embodiment, the normal write operation S10 may include a set write operation and a reset write operation. For example, the normal write operation S10 may include an operation for providing the first positive bias voltage V_PN to the selected bit line Selected Bit Line and providing the first negative bias voltage V_NN to the selected word line Selected Word Line in order to make the memory cell MC have the set state. The normal write operation S10 may also include an operation for providing the first positive bias voltage V_PN to the selected word line Selected Word Line and providing the first negative bias voltage V_NN to the selected bit line Selected Bit Line in order to make the memory cell MC have the reset state.

The operation S20 may include an operation for determining the required reliability of data to be stored in the memory cell MC. When the data to be stored in the memory cell MC requires specific reliability (e.g., relatively high reliability) (Y), the acceleration shift operation S30 may be performed on the memory cell MC. For example, when the data to be stored in the memory cell MC is firmware, root data, or both, the acceleration shift operation S30 may be performed on the memory cell MC. However, when the data to be stored in the memory cell MC does not require the high reliability (N), for example, when the location of the memory cell MC is in an area other than the specific area, the operating method of the semiconductor device in accordance with an embodiment of the present disclosure may be ended by skipping the acceleration shift operation S30.

For example, the operation S20 may be performed on the basis of the address signal ADD. The memory cell array 500 included in the semiconductor device may include a specific area for storing data requiring relatively high reliability. Specifically, such a specific area of the memory cell array 500 may be assigned to store data requiring relatively high reliability, for example, firmware, root data, or the like. Accordingly, the operation S20 may cause the acceleration shift operation S30 to be performed when the address signal ADD indicates the specific area for storing data requiring relatively high reliability (Y). The operation S20 may cause the operating method of the semiconductor device in accordance with an embodiment of the present disclosure to be ended when the address signal ADD indicates an area other than the specific area for storing data requiring high reliability (N).

The acceleration shift operation S30 may include an operation for increasing the threshold voltage level of the memory cell MC in the set state or the reset state by applying, for a set time interval, the third positive bias voltage V_PA and the third negative bias voltage V_NA to the memory cell MC subjected to the normal write operation S10.

The set state recovery operation S40 may be an operation for providing the second positive bias voltage V_PC and the second negative bias voltage V_NC to the memory cell MC after the acceleration shift operation S30. In such a case, the second positive bias voltage V_PC may be applied to a bit line connected to the memory cell MC, that is, the selected bit line Selected Bit Line, and the second negative bias voltage V_NC may be applied to a word line connected to the memory cell MC, that is, the selected word line Selected Word Line. That is, the set state recovery operation S40 may be an operation for causing a current to flow through the memory cell MC in the same direction as in a set write operation, and providing the voltages V_PC and V_NC with a voltage level difference lower than a difference in the voltage levels of a bit line and a word line provided to the memory cell MC in the set write operation to the memory cell MC. Accordingly, the set state recovery operation S40 may be an operation for recovering the set state of the memory cell MC, whose threshold voltage level has been increased by the acceleration shift operation S40, back to the threshold voltage level in the set state formed by the normal write operation S10. In other words, the set state recovery operation S40 may decrease the threshold voltage level of the memory cell MC increased by the acceleration shift operation S30, according to whether the memory cell has the set state or the reset state. Specifically, when the memory cell MC has the set state, the increased threshold voltage level of the memory cell MC may be decreased substantially to that in the set state formed by the normal write operation S10. When the memory cell MC has the reset state, the increased threshold voltage level of the memory cell MC may be kept at substantially the same level.

Therefore, the operating method of the semiconductor device in accordance with an embodiment of the present disclosure may perform only a normal write operation on a memory cell, or may perform an additional operation on the memory cell for widening a margin between a set state and a reset state compared to that after performing the normal write operation, depending on whether data to be stored in the memory cell requires specific reliability or not.

Although embodiments according to the technical idea of the present disclosure have been described above with reference to the accompanying drawings, this is only for explaining the embodiments according to the concept of the present disclosure, and embodiments of the present disclosure are not limited to the above-described embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of embodiments of the present disclosure.

What is claimed is:

1. A semiconductor device comprising:
a memory cell array including a plurality of memory cells arranged at locations where a plurality of word lines intersect with a plurality of bit lines;
a row decoder configured to drive the plurality of word lines; and
a column decoder configured to drive the plurality of bit lines,
wherein each of the plurality of memory cells has a set state or a reset state according to a normal write operation performed thereon, the plurality of memory cells include first memory cells in a specific area of the memory cell array, and the row decoder and the column decoder control a bit line and a word line coupled to a corresponding one of the first memory cells to increase a margin between the set state and the reset state of the corresponding first memory cell.

2. The semiconductor device of claim 1, further comprising:
a control circuit configured to determine a location of each of the memory cells on which the normal write operation is performed according to an address.

3. The semiconductor device of claim 2, wherein, after the normal write operation is performed, the control circuit controls the row decoder and the column decoder to drive the bit line and the word line coupled to the corresponding one of the first memory cells in the specific area.

4. The semiconductor device of claim 3, wherein, the control circuit controls the row decoder and the column decoder to drive the bit line and the word line for a set time interval to apply a third voltage difference to the corresponding one of the first memory cells, the third voltage difference applied for the set time interval being smaller than a first voltage difference applied during the normal write operation, and
wherein, after the set time interval, the control circuit further controls the row decoder and the column decoder to drive the bit line and the word line to apply a second voltage difference to the corresponding one of the first memory cells.

5. The semiconductor device of claim 4, wherein, when the control circuit further controls the row decoder and the column decoder to drive the bit line and the word line to apply the second voltage difference after the set time interval, the second voltage difference is greater than the third voltage difference and smaller than the first voltage difference, and the bit line is driven to a voltage level higher than that of the word line.

6. A semiconductor device comprising:
a control circuit configured to generate a current direction control signal, a row address signal, and a column address signal on the basis of a command signal, an address signal, and a data signal;
a current direction control circuit configured to provide a positive bias voltage to one of a row voltage line and a column voltage line on the basis of the current direction control signal, and to provide a negative bias voltage to the other voltage line, the positive bias voltage being one of a first positive bias voltage, a second positive bias voltage, and a third positive bias voltage, the negative bias voltage being one of a first negative bias voltage, a second negative bias voltage, and a third negative bias voltage corresponding to the positive bias voltage;
a memory cell array including a plurality of memory cells arranged at locations where a plurality of word lines intersect with a plurality of bit lines;
a row decoder configured to select at least one word line from the plurality of word lines on the basis of the row address signal, and to drive the selected word line to a voltage level of the row voltage line; and
a column decoder configured to select at least one bit line from the plurality of bit lines on the basis of the column address signal, and to drive the selected bit line to a voltage level of the column voltage line.

7. The semiconductor device of claim 6, wherein, when the command signal is a write command, the control circuit generates the current direction control signal on the basis of the address signal and the data signal.

8. The semiconductor device of claim 7, wherein, a level of the second positive bias voltage is lower than that of the first positive bias voltage and higher than that of the third positive bias, and
wherein a level of the second negative bias voltage is higher than that of the first negative bias voltage and is lower than that of the third negative bias voltage.

9. The semiconductor device of claim 8, wherein, when the data signal indicates set data, the control circuit generates the current direction control signal to provide the first positive bias voltage to the column voltage line and the first negative bias voltage to the row voltage line, and
wherein, when the data signal indicates reset data, the control circuit generates the current direction control signal to provide the first negative bias voltage to the column voltage line and the first positive bias voltage is provided to the row voltage line.

10. The semiconductor device of claim 6, wherein the plurality of memory cells including first memory cells each having a set state and second memory cells each having a reset state,
wherein a level difference between the third positive bias voltage and the third negative bias voltage is smaller than a level of a minimum threshold voltage in a threshold voltage distribution of the first memory cells, and
wherein a level difference between the second positive bias voltage and the second negative bias voltage is smaller than a level of a minimum threshold voltage in a threshold voltage distribution of the second memory cells.

11. The semiconductor device of claim 10, wherein the level difference between the third positive bias voltage and the third negative bias voltage is in a range from about 50% to 98% of the level of the minimum threshold voltage in the threshold voltage distribution of the first memory cells, and
wherein the level difference between the second positive bias voltage and the second negative bias voltage is from about 80% to about 100% of the level of the minimum threshold voltage in the threshold voltage distribution of the second memory cells.

12. The semiconductor device of claim 10, wherein the control circuit determines a location where data indicated by the data signal is stored on the basis of the address signal, and when the determined location is in a specific area, the control circuit generates the current direction control signal to apply the third positive bias voltage and the third negative bias voltage for a set time interval.

13. The semiconductor device of claim 12, wherein the memory cell array includes the specific area for storing data requiring reliability.

14. The semiconductor device of claim 13, wherein the specific area stores the data including firmware, or root data, or both.

15. The semiconductor device of claim 12, wherein, after the third positive bias voltage and the third negative bias voltage are applied for the set time interval, the control circuit generates the current direction control signal to apply the second positive bias voltage to the column voltage line and the second negative bias voltage to the row voltage line.

16. An operating method of a semiconductor device, the operating method comprising:
performing a normal write operation to make a memory cell have a set state or a reset state;
determining required reliability of data stored in the memory cell;
increasing, in response to the determination, a threshold voltage level of the memory cell; and
decreasing the increased threshold voltage level of the memory cell according to whether the memory cell has the set state or the reset state.

17. The operating method of claim 16, wherein the performing of the normal write operation comprises:
providing a first positive bias voltage to a selected bit line and providing a first negative bias voltage to a selected word line, to make the memory cell have the set state.

18. The operating method of claim 17, wherein the performing of the normal write operation further comprises:
providing the first positive bias voltage to the selected word line and providing the first negative bias voltage to the selected bit line, to make the memory cell have the reset state.

19. The operating method of claim 18, wherein the determining of the required reliability of data comprises:
determining whether a location of the memory cell is in a specific area.

20. The operating method of claim 19, wherein the specific area stores the data including firmware, or root data, or both.

21. The operating method of claim 19, wherein the increasing of the threshold voltage level of the memory cell is performed when the location of the memory cell is in the specific area.

22. The operating method of claim 21, wherein the increasing of the threshold voltage level of the memory cell is skipped when the location of the memory cell is in an area other than the specific area.

23. The operating method of claim 18, wherein the increasing of the threshold voltage level of the memory cell comprises:
applying a third positive bias voltage to one of the selected bit line and the selected word line for a set time interval; and
applying a third negative bias voltage to the other line for the set time interval.

24. The operating method of claim 23, wherein the decreasing of the increased threshold voltage level of the memory cell comprises:
applying a second positive bias voltage to the selected bit line; and
applying a second negative bias voltage to the selected word line.

25. The operating method of claim 24, wherein a level of the second positive bias voltage is lower than that of the first positive bias voltage and higher than a level of the third positive bias voltage, and
wherein a level of the second negative bias voltage is higher than that of the first negative bias voltage and is lower than that of the third negative bias voltage.

26. The operating method of claim 25, wherein a plurality of memory cells of the semiconductor device includes first memory cells and second memory cells, and the normal write operation is performed to make each of the first memory cells have the set state and each of the second memory cells have the reset state,
wherein a level difference between the third positive bias voltage and the third negative bias voltage is smaller than a level of a minimum threshold voltage in a threshold voltage distribution of the first memory cells, and
wherein a level difference between the second positive bias voltage and the second negative bias voltage is smaller than a level of a minimum threshold voltage in a threshold voltage distribution of the second memory cells.

27. The operating method of claim 26, wherein the level difference between the third positive bias voltage and the third negative bias voltage is in a range from about 50% to 98% of the level of the minimum threshold voltage in the threshold voltage distribution of the first memory cells, and
wherein the level difference between the second positive bias voltage and the second negative bias voltage is from about 80% to about 100% of the level of the minimum threshold voltage in the threshold voltage distribution of the second memory cells.
